(19) United States
(12) Patent Application Publication
(10) Pub. No.: US 2026/0300704 A1
(43) Pub. Date: Oct. 1, 2026

(54) METHOD AND APPARATUS FOR ENCODING OR DECODING A COMPRESSED NEURAL NETWORK BITSTREAM

(71) Applicant: CANON KABUSHIKI KAISHA, Tokyo (JP)

(72) Inventors: Romain BELLESSORT, SAINT GREGOIRE (FR); Frédéric MAZE, LANGAN (FR); Franck DENOUAL, SAINT DOMINEUC (FR); Naël OUEDRAOGO, VAL D'ANAST (FR); Lionel TOCZE, SAINT DOMINEUC (FR)

(21) Appl. No.: 19/480,750

(22) PCT Filed: Apr. 9, 2024
(86) PCT No.: PCT/EP2024/059626

§ 371 Date: Oct. 31, 2025

(30) Foreign Application Priority Data
May 11, 2023 (GB) 2307032.9

(51) Int. Cl. G06N 3/0495

(52) U.S. Cl. CPC G06N 3/0495

(57) ABSTRACT

The present invention concerns a method of encoding one or more versions of a neural network model in a Neural Network Representation, NNR, bitstream of logical units, the method comprising: generating descriptive data describing at least some of the one or more versions of the neural network model; and encoding the descriptive data and the one or more versions of the neural network model in logical units of the NNR bitstream, the descriptive data being encoded in one or more logical units comprising information applying to multiple logical units.

### FIELD OF THE INVENTION

The present disclosure concerns a method and a device for encoding or decoding a compressed neural network bitstream. It concerns more particularly the description of the different model versions in the bitstream.

### BACKGROUND OF INVENTION

MPEG-7 Part 17 (ISO/IEC 15938-17) defines means for compressing Neural Networks (NN). Each compressed neural network results in a so-called Neural-Network Representation (NNR) bitstream, which consists in a list of NNR units that complies with syntax rules. NNR units carry compressed or uncompressed information about neural network metadata, topology information, complete or partial layer data, filters, kernels, biases, quantized weights, tensors or alike. An NNR unit consists of the following data elements:
NNR unit size: This data element signals the total byte size of the NNR unit, including the NNR unit size.
NNR unit header: This data element contains information about the NNR unit type and related metadata.
NNR unit payload: This data element contains compressed or uncompressed data related to the neural network.

In particular, an NNR bitstream may start by an NNR unit of type NNR_STR (start unit), and comprises an NNR_MPS (model parameter set) unit that describes global metadata and information about a considered neural network. An NNR bitstream also comprises one or more NNR_NDU units that contain compressed neural network data. Usually, there is a single NNR_MPS in an NNR bitstream which precedes any NNR_NDU. Additionally, an NNR bitstream may also comprise the following unit types:
NNR_LPS (layer parameter set) unit: metadata related to a partial representation of neural network; such unit is active until another NNR_LPS unit occurs, or until the end of an aggregate NNR unit (see below);
NNR_TPL (topology) unit: metadata related to neural network topology;
NNR_QNT (quantization) unit: metadata related to quantization information;
NNR_AGG (aggregate) unit: unit whose payload comprises multiple NNR units.

NNR_TPL or NNR_QNT units; if present in the NNR bitstream; usually precede any NNR_NDUs that reference their data structures.

MPEG-7 Part 17 defines the concept of a base version of a neural network as well as an updated version of a neural network using incremental updates. An incremental update modifies a given element of a base version, for example it changes the parameters associated to a given layer of the neural network. Incremental updates may also apply to a previous incremental update. MPEG-7 Part 17 is defined in a flexible way, with few constraints on what may be comprised in a bitstream. In particular, there is no means to easily determine whether a bitstream comprises a base and/or updates without parsing all NNR units headers, which is clearly not optimal.

### SUMMARY OF THE INVENTION

The present invention has been devised to address one or more of the foregoing concerns. It concerns adding some information to the NNR bitstream so that it may be possible to determine whether an NNR bitstream comprises a base model and/or model updates by parsing a limited number of NNR units. The description of the data describing the one or more versions is comprised in a bitstream level NNR unit, meaning a NNR unit that contains information common to, i.e., information mutualised by and/or applying to, multiple NNR units (E.g., all NNR units of the whole NNR bitstream or only a subset of all NNR units (e.g., NNR units belonging to several layers or to several model versions)). For instance, such bitstream level NNR unit may be an NNR unit with type NNR_STR/NNR_MPS/NNR_LPS/NNR_AGG or another dedicated NNR unit. Different types of descriptive information related to the versions may be encoded, such as the presence of a base version and/or updates versions, the relationship between model versions, some properties of a model version (e.g., creation time, creation order, priority value, human-readable description . . . ), and access points to the NNR units associated with each model version. All that data may be useful to a decoder application, for instance to determine in an efficient way a list of model versions comprised in a given bitstream and their relationships, or to extract a given model version from an NNR bitstream. Depending on embodiments, descriptive information may be comprised in a single NNR unit, typically at the beginning of the stream, e.g. an NNR unit with type NNR_STR/NNR_MPS or another bitstream level NNR unit, or split in different NNR units, each NNR unit applying to multiple NNR units throughout the NNR bitstream.

In the following, the notation “NNR_xxx unit” is equivalent to a “NNR unit with a type NNR_xxx” where xxx identifies a specific type of NNR units.

According to a first aspect of the invention there is provided a method of a method of encoding one or more versions of a neural network model in a Neural Network Representation, NNR, bitstream of logical units, the method comprising:
generating descriptive data describing at least some of the one or more versions of the neural network model;
encoding the descriptive data and the one or more versions of the neural network model in logical units of the NNR bitstream, the descriptive data being encoded in one or more logical units comprising information applying to multiple logical units.

In an embodiment, the descriptive data comprises at least one of the following:
indication of a type of a version of the neural network model;
indication of a number of versions of the neural network model corresponding to an update of the neural network model;
indication of an identifier of a version of the neural network model;
indication of a dependence of a version of the neural network model with another version of the one or more versions of the neural network model;
indication of a creation time of a version of the neural network model;
indication ordering different versions of the neural network model;
indication of a complexity of a version of the neural network model;
human-readable description of a version of the neural network model.

In an embodiment, the descriptive data is encoded in a logical unit comprising information applying to the whole NNR bitstream.

In an embodiment, at least some of the descriptive data is encoded in a logical unit comprising information applying to a subset of the logical units of the NNR bitstream.

In an embodiment, at least some of the descriptive data is encoded in a logical unit comprising information applying to the whole NNR bitstream

In an embodiment, at least some of the descriptive data is encoded in a header of a logical unit aggregating two or more logical units of the NNR bitstream.

In an embodiment, the descriptive data comprise an access point associated with a version of the neural network model, the access point referencing a logical unit of the NNR bitstream corresponding to this version of the neural network model.

According to another aspect of the invention there is provided a method of decoding one or more versions of a neural network model from a Neural Network Representation, NNR, bitstream of logical units, the method comprising:
decoding descriptive data describing at least some of the one or more versions of the neural network model, the descriptive data being decoded from one or more logical units comprising information applying to multiple logical units;
decoding the one or more versions of the neural network model in logical units of the NNR bitstream based on the descriptive data.

According to another aspect of the invention there is provided a computer program product for a programmable apparatus, the computer program product comprising a sequence of instructions for implementing a method according to the invention, when loaded into and executed by the programmable apparatus.

According to another aspect of the invention there is provided a computer-readable storage medium storing instructions of a computer program for implementing a method according to the invention.

According to another aspect of the invention there is provided a computer program which upon execution causes the method of the invention to be performed.

According to another aspect of the invention there is provided a device for encoding one or more versions of a neural network model in a Neural Network Representation, NNR, bitstream of logical units, the device comprising a processor configured for:
generating descriptive data describing at least some of the one or more versions of the neural network model;
encoding the descriptive data and the one or more versions of the neural network model in logical units of the NNR bitstream, the descriptive data being encoded in one or more logical units comprising information applying to multiple logical units.

According to another aspect of the invention there is provided a device for decoding one or more versions of a neural network model from a Neural Network Representation, NNR, bitstream of logical units, the device comprising a processor configured for:
decoding descriptive data describing at least some of the one or more versions of the neural network model, the descriptive data being decoded from one or more logical units comprising information applying to multiple logical units;
decoding the one or more versions of the neural network model in logical units of the NNR bitstream based on the descriptive data.

At least parts of the methods according to the invention may be computer implemented. Accordingly, the present invention may take the form of an entirely hardware embodiment, an entirely software embodiment (including firmware, resident software, micro-code, etc.) or an embodiment combining software and hardware aspects that may all generally be referred to herein as a “circuit”, “module” or “system”. Furthermore, the present invention may take the form of a computer program product embodied in any tangible medium of expression having computer usable program code embodied in the medium.

Since the present invention can be implemented in software, the present invention can be embodied as computer readable code for provision to a programmable apparatus on any suitable carrier medium. A tangible, non-transitory carrier medium may comprise a storage medium such as a floppy disk, a CD-ROM, a hard disk drive, a magnetic tape device or a solid state memory device and the like. A transient carrier medium may include a signal such as an electrical signal, an electronic signal, an optical signal, an acoustic signal, a magnetic signal or an electromagnetic signal, e.g. a microwave or RF signal.

### BRIEF DESCRIPTION OF THE DRAWINGS

Embodiments of the invention will now be described, by way of example only, and with reference to the following drawings in which:

FIGS. 1a, 1b, and 1c illustrate the general structure of a compressed neural network representation bitstream, or NNR bitstream;

FIG. 2 illustrates the main steps of a method for encoding a compressed neural network representation according to embodiments of the invention;

FIG. 3 illustrates the main steps of a method for encoding of the descriptive data generated at step 210 according to embodiments of the invention;

FIG. 4 illustrates the main steps of a method for parsing or decoding an NNR bitstream created according to embodiments of the invention in view of extracting a given model version of a neural network;

FIGS. 5a and 5b provides an example syntax for integrating version description information into the NNR_MPS unit syntax according to an embodiment of the invention and the corresponding bitstream;

FIGS. 6a and 6b illustrates another embodiment of the invention;

FIGS. 7a, 7b, 7c, and 7d illustrate a further embodiment of the invention;

FIGS. 8a and 8b illustrate an embodiment of the invention that is an alternative of the previous embodiment;

FIG. 9 is a schematic block diagram of a computing device for implementation of one or more embodiments of the invention.

### DETAILED DESCRIPTION OF THE INVENTION

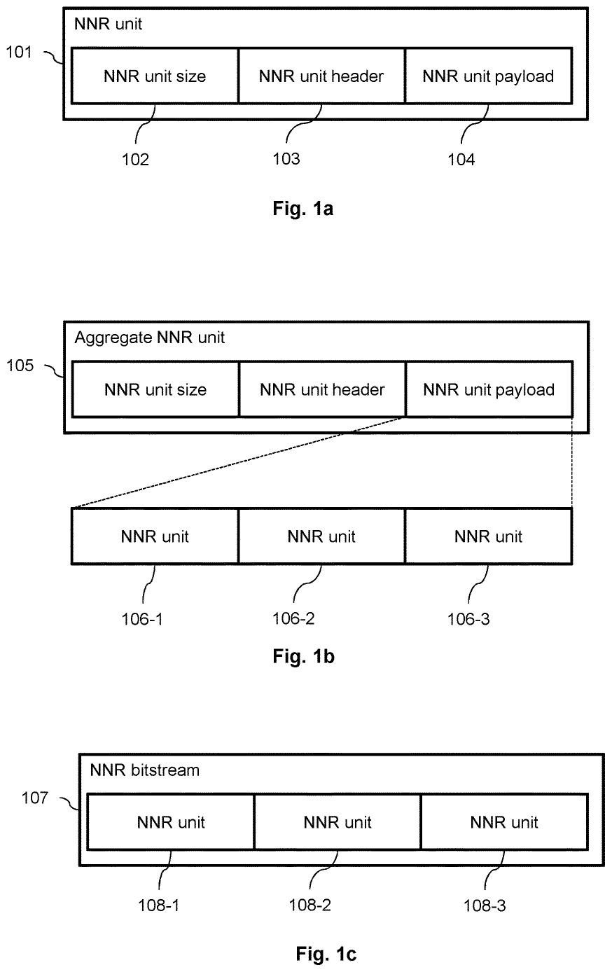

FIGS. 1a, 1b, and 1c illustrate the general structure of a compressed neural network representation bitstream, or NNR bitstream.

An NNR bitstream is composed of logical units called NNR units illustrated in FIG. 1a. Each NNR unit 101 is composed of three fields 102, 103, and 104. The first field 102 is the NNR unit size indicating the byte size of the NNR unit including the NNR unit size. It is followed by the NNR unit header 103, which contains information about the NNR unit type and related metadata. The metadata in the NNR unit header depends on the particular type of the NNR unit. The third field 104 is the NNR unit payload and comprises compressed or uncompressed data related to the neural network.

FIG. 1b illustrates a particular type of NNR unit called aggregate NNR unit. An aggregate NNR unit 105 is an NNR unit and has the same structure illustrated in FIG. 1a. Its payload is composed of the concatenation of a plurality of NNR units 106-1, 106-2, and 16-3. The number of NNR units in an aggregate NNR unit is arbitrary and not limited by the illustrated example of three NNR units.

FIG. 1c illustrates the NNR bitstream 107 composed of the concatenation of an arbitrary number of NNR units 108-1, 108-2, and 108-3.

A compressed neural network representation may comprise a base neural network, which is a self-contained neural network comprising all the data defining a particular neural network model. A compressed neural network representation may also comprise a neural network update. A neural network update is composed of data for updating another neural network model called the reference model of the update model. The reference model of an update model may be a base model or another update model. This creates a tree of models which may have different branches. For example, a base model may be updated by two different update models, which may themselves be updated by other update models.

In this document, a version of a neural network corresponds either to a base neural network model or to an update model. An update model version is not sufficient for generating the associated neural network. The data corresponding to the reference model it applies to are required.

At least some of the data of an update model may be encoded as residuals, meaning that theses residuals are differences between the data of the update model and corresponding data of the reference model. In this case, the data of the reference model are required for the decoding of the data of the update model. When no data of the update model are encoded as residuals, the update model is said to be independently encoded. A base model is always independently encoded. It is to be noted that while the data of the reference model are not required for the decoding of an independently encoded update model, they are still required after decoding for generating the corresponding neural network.

Some base neural network are known. Accordingly, a NNR bitstream may only comprise one or more neural network model updates, the base model being identified by a known neural network model identifier.

In summary, a NNR bitstream may comprise zero or one base neural network model and one or more neural network updates each corresponding to a respective version of the neural network.

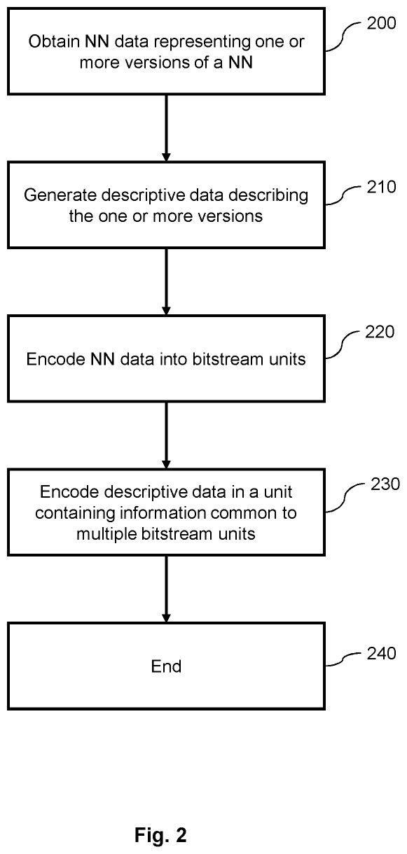

FIG. 2 illustrates the main steps of a method for encoding a compressed neural network representation according to embodiments of the invention.

In a step 200, neural network data is obtained which represent one or more versions of a neural network. The neural network data typically comprise parameters of a neural network, such as weights and biases. In addition, it may also comprise topological information describing the neural network topology, information related to the neural network model, information related to a specific layer of the neural network, and information related to compression modes such as quantization parameters for instance.

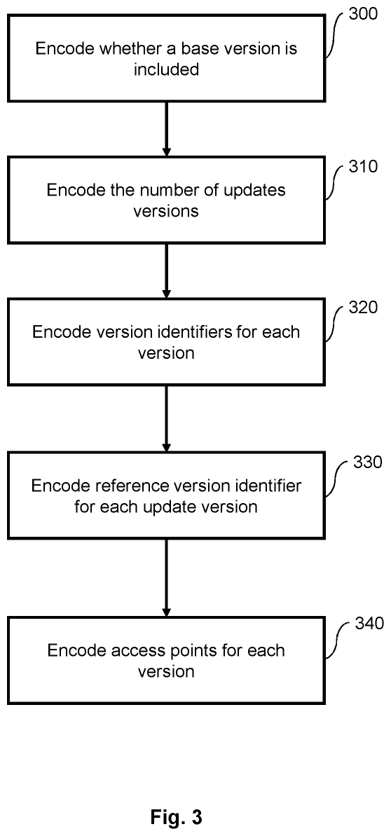

In a step 210, descriptive data describing the one or more versions is generated. In some embodiments, descriptive data may only describe a subset of all the versions of the neural network model in the bitstream instead of all the versions. As described in more details with regards to FIG. 3, these descriptive data may comprise one or more of the following information:
whether a base is comprised in the one or more versions;
whether an update is comprised in the one or more versions;
the number of updates comprised in the one or more versions;
an identifier of a version;
an identifier of a reference version on which is based an update version;
an association between a version and one or more NNR units;
an access point to one or more NNR units associated to a given version.

Additionally, in some embodiments, other properties characterizing a version may be part of the descriptive data. For instance, for a version, its creation time may be indicated. As another example, a value enabling to order the different versions may be indicated for each version. A third example may be to indicate, for a version, an indication about its complexity, so that an application may determine whether it may run it or not. In the case where an identifier of a version is indicated, especially if it is indicated as a string, the identifier may be used to represent indications as described in this paragraph. A fourth example may be to indicate, for a version, a human-readable description or name of the version that can be exposed to a user to allow him selecting an appropriate model version from the bitstream.

According to some embodiments, the reference model version identifier may be representative of a decoding dependency between neural network model versions or of a processing order between independently decodable neural network model versions.

In a step 220, neural network data is encoded into bitstream units, e.g. NNR units. This step is performed by the NNR encoder according to considered NNR specification. Some of the units encoded at step 220 typically comprise information specific to a given version (e.g. weights of a given layer of a neural network), while other units may comprise information that may be common to multiple versions (e.g. NNR_MPS unit, which is common to all versions, or NNR_LPS unit, that may be specific to a version or common to different versions depending on cases). If the encoder aims at enabling random access to the different versions, it should adapt the compression means so that each version is independently decodable.

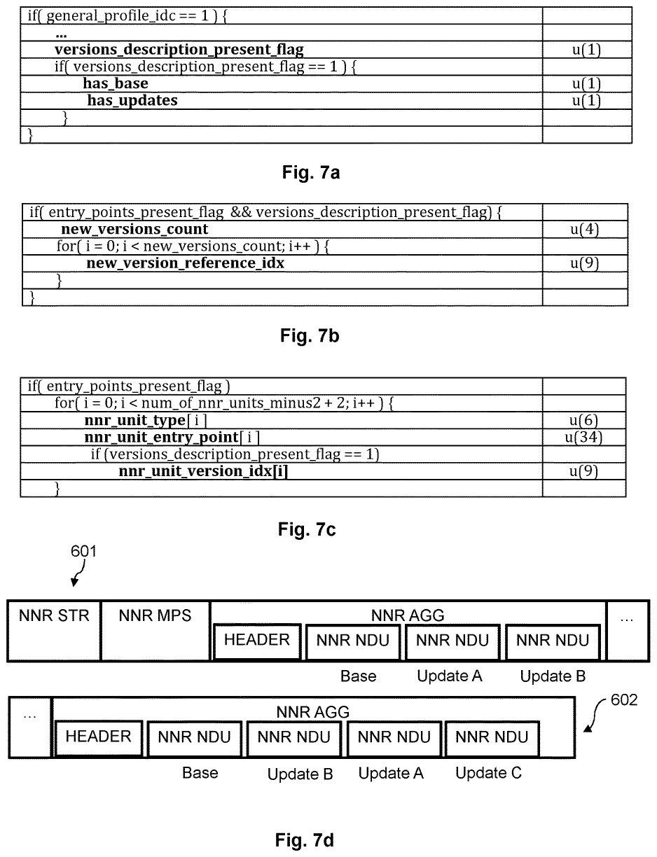

In a step 230, some of the descriptive data generated at step 210 is encoded in a unit containing bitstream level information, meaning information common to multiple bitstream units. The unit wherein descriptive data is encoded at step 230 may be one of a unit comprising information common to multiple bitstream versions involved in step 220. Also, please note that the step 230 may be performed several times, for instance if the descriptive information generated at step 210 is split over different units. Examples of this are illustrated in FIGS. 7a, 7b, 7c and 7d.

Generally speaking, an encoder generally obtains data to encode through an API. So that neural network data may be associated to a version, an NNR bitstream encoder may provide an API adapted to do so. For instance, such an API may allow specifying, for each neural network data provided to an encoder, a version identifier. Alternatively, an encoder may provide an API that allows defining a current version, in which case an application may indicate to an encoder a current version, then provides the encoder with neural network data, in which case said neural network data is considered to be associated to the current version.

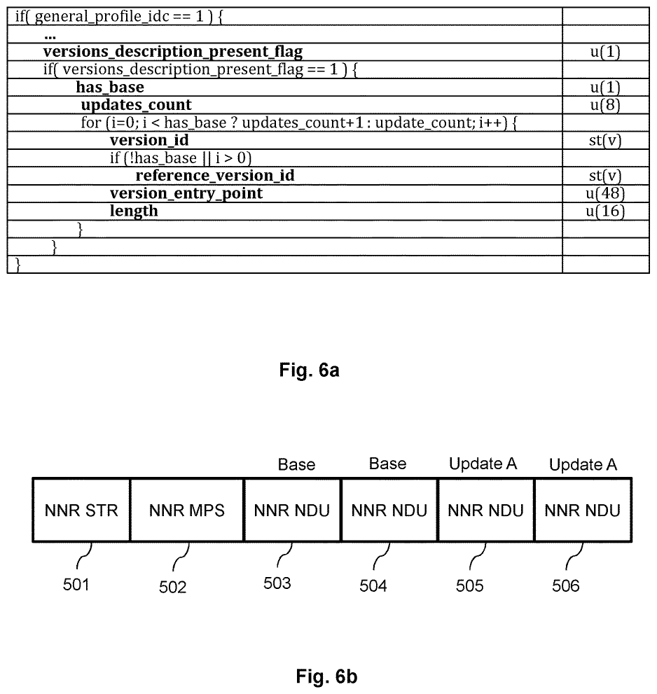

In a specific embodiment, the neural network data obtained at step 200 may come from a previously existing NNR bitstream. In this case, the invention may be used in view of creating an alternative representation of the NNR bitstream, the alternative representation being more convenient to use thanks to the descriptive information that has been added to the bitstream. In some embodiments, the creation of this new representation may also involve reorganizing the bitstream, for instance to make each version independently decodable, and possibly to make all the NNR units of a given version contiguous, as illustrated for example by FIG. 6b, so that they can be efficiently extracted. While this new representation may be less compact than the original one, the benefits for applications using NNR bitstream would overcome the drawbacks in scenarios where the size of the bitstream is not critical.

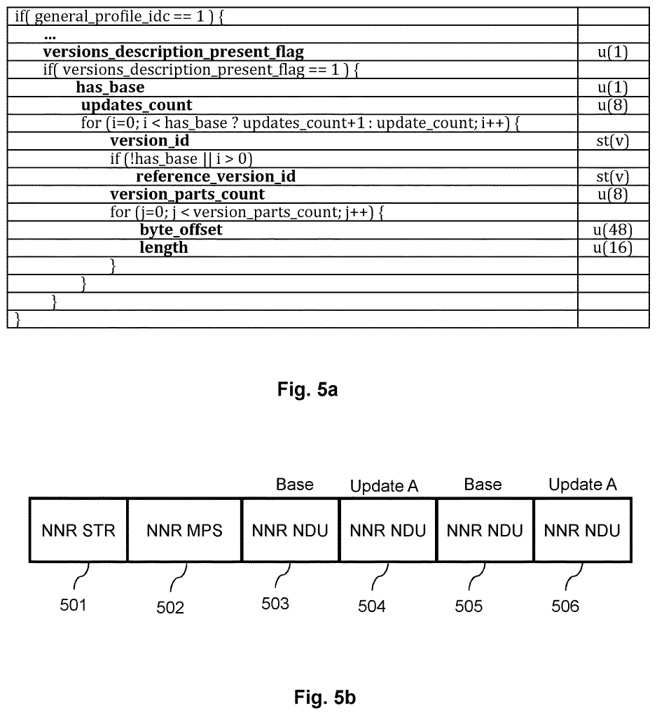

FIG. 3 illustrates the main steps of a method for encoding of the descriptive data generated at step 210 according to embodiments of the invention. Please note that none of the described step is mandatory, as the benefits of encoding each type of descriptive information may depend on considered use case. However, at least one of this step must be performed. More specific embodiments are described with regards to FIGS. 5 to 7.

In a step 300, an information indicating whether a base version is included in the NNR bitstream is encoded. This allows a decoder application to determine whether a base version is present or not in the bitstream, which may be convenient for applications that are interested in identifying base versions. For example, the decoder may then be able to list all the different NNs from a repository of NNR bitstreams, or because a given application knows that the base version is sufficient for the type of processing it aims at doing.

Then, at step 310, an indication of the number of updates versions is encoded in the NNR bitstream. Doing so allows a decoder application to determine whether updates are present. Alternatively, only a Boolean indicating whether at least one update version is present may be encoded. However, indicating the number of updates versions gives a more accurate indication on the content of the bitstream.

At step 320, an identifier is encoded for identifying each version present in the NNR bitstream. Version identifier may be for instance a string or an integer. In the case where the version is an integer, it may be decided not to encode the version identifier, and instead use an implicit identifier that corresponds to the index of the considered version in the bitstream. For instance, the base would typically be indicated through index 0, the first update through index 1, the second update through index 2, etc. An advantage of enabling each version to be represented by an explicit version identifier is that it allows applications to distinguish the different versions not only inside a given bitstream, but also among different bitstreams.

In another variant, a version identifier is encoded for some of the versions only. In this variant, a version identifier is encoded only for the version that are referred by another version for dependency purpose. This may be useful when the dependencies between versions is hierarchically organized as a tree or a chained structure. In such case, the versions corresponding to a leaf do not need an explicit identifier.

At step 330, for each update version, the version identifier of the version of the reference model of the update is encoded. For instance, if a first update is based on the base model, then the version identifier of the base model is encoded as a reference version identifier. As another example, if a second update is based on the first update, then the version identifier of the first update model is encoded as a reference version identifier. Encoding such information allows explicitly describing the relationship between the different model versions. For instance, this would allow an application processing the bitstream associated to previous example to determine that the latest version is the second update. Understanding the dependencies between model versions is also helpful in that it allows determining which model versions have to be decoded in order to extract a given model version. For example in the previous example, the decoding of the first update model version requires the decoding of the base model version since the first update model version is based on the base version.

According to alternative variants, the reference model version identifier may be representative of a decoding dependency between neural network model versions or of a processing order between independently decodable neural network model versions.

At step 340, access points are encoded for each model version. This allows a decoder to efficiently extract a given model version. Practically, an access point corresponds to the address in the bitstream of the first byte of an NNR unit associated with the given model version. Generally speaking, for each model version, a list of access points may be provided, each access point being associated with a parameter indicative of the amount of data associated to the model version starting from said access point. This parameter may be expressed as a length or an offset, in bytes or in a number of NNR units. In some cases, an access point is provided for each NNR unit belonging to a given model version, in which case the length may not be indicated as a similar information can be obtained from the header of the corresponding NNR unit which indicates its length. In some embodiments, the organization of the bitstream may be constrained when a descriptive information is carried in the stream. For instance, model versions may be sequentially organized, with e.g. the NNR units of the base coming first, then the NNR units of the first update, then the NNR units of the second updates. In such a case, a single access point may be provided for each model version, possibly with a length indication, unless the length can be determined from said NNR units (e.g. if we consider the additional constraint of describing a given model version in a single NNR_AGG unit, then the length in bytes can be determined from said NNR_AGG header).

Different types of indications related to the model versions present in the bitstream may be encoded in different bitstream units (e.g. in different NNR units). Ideally, providing as many indications as possible on the available versions at the beginning of the bitstream is more convenient for a decoder application as it allows obtaining very efficiently that descriptive information. However, it may for instance not always be possible to know all the versions when starting to encode a bitstream. In such a case, it may be decided to include only some indications in a bitstream unit present at the beginning of the stream, for example NNR_MPS or any other bitstream-level NNR unit. These information may comprise, for example, whether a base is present, or whether updates are present if this can be determined. Then, additional information may be provided throughout the NNR bitstream, through other bitstream units. This is for instance illustrated by FIGS. 7a, 7b, 7c and 7d. In such cases, it may be advantageous to include, inside each NNR unit containing descriptive data describing the one of more model versions comprised in the bitstream, an indication such as an access point regarding the location of the next NNR unit that contains such descriptive data. In the case where there is no such next NNR unit, an indication that the current NNR unit is the last such NNR unit may be provided, for example by defining a null value for the access point associated to the next such NNR unit.

In order for a NNR bitstream decoder application to know when it has reached the end of a model version, it may be useful to indicate, in the NNR bitstream, when the end of a model version has been reached. The end of a version may be indicated through different means.

If a model version is described as a list of access points, the last access point indicate the start of the last portion of the NNR bitstream associated with the version; once decoded, the decoder knows that the end of the version has been reached.

If a model version is described through multiple lists of access points, for example split throughout the NNR bitstream, then, an indication may be provided for each list to indicate whether the list of access points is the last one for the considered model version. Alternatively, such an indication may also be provided for each access point, this may especially be the case if each list of access points comprises a single entry.

As another alternative, each NNR unit may comprise, in its header, an indication of whether the NNR unit is the last one for its associated model version.

Finally, another solution may consist in adding an explicit marker indicating the end of a model version, for instance this marker may be a new type of NNR unit.

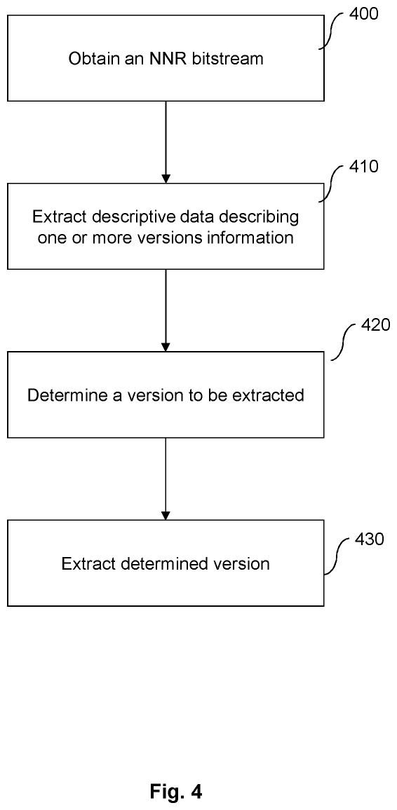

FIG. 4 illustrates the main steps of a method for parsing or decoding an NNR bitstream created according to embodiments of the invention in view of extracting a given model version of a neural network.

In a step 400, an NNR bitstream encoded according to embodiments of the invention is obtained.

In a step 410, the descriptive data describing the one or more model versions is extracted from the NNR bitstream. Depending on embodiments, this may only require decoding a given NNR unit present at the beginning of the NNR bitstream, for example the NNR_MPS unit or any other bitstream-level NNR unit, or it may require decoding some of the NNR units present throughout the bitstream.

In a step 420, the model version to be extracted is determined. This may for example involve indicating the different model versions present in the NNR bitstream to an application or to a user, so that application or user may select a particular model version. Alternatively, a policy may be defined to determine the model version to be extracted, for instance the base version if any.

In a step 430, the determined model version is extracted. If a model update is extracted, it may be necessary to also extract one or more additional model versions in order to obtain all the data needed to create the corresponding neural network, for instance, in order to create a neural network corresponding to an update model version that is based on a base model version, the base model version has to be decoded. If the relationship between model versions is indicated in the bitstream using embodiments of the invention for example through steps 320 and 330, the model versions that a given model version depends on can be determined from the descriptive data encoded at step 230. If this is not the case, the dependency may be determined by parsing all the NNR units of the NNR bitstream, which is less efficient. Also, if the relationship between model versions is not encoded as described by embodiments of the invention, it may not be possible to determine which incremental model updates are together associated with a given model version. Indeed, each incremental model update is associated with a model reference that it updates, but there is no means to indicate that two incremental model updates are associated with the same model version. As an example, if we consider a base model comprising two different layers, L1 and L2, an update of this base model may comprise an update of the layer L1, namely L1′, and an update of the layer L2, namely L2′. In the case where the two parts L1′ and L2′ of the update are encoded in two respective different NNR units, the prior art does not allow to indicate that the two NNR units comprising L1′ and L2′ are actually part of a same update and should be considered together. According to the invention, these two different NNR units comprising L1′ and L2′ are described as part of a same version. Accordingly, a decoder is aware that either it must generate the base model or the update model with both L1′ and L2′. A model combining a layer of the base model and a layer of the update, namely L1 and L2′ or L1′ and L2, must not be generated. Practically, an update model version is defined, and it is indicated in the NNR bitstream that the NNR units corresponding to L1′ and L2′ are associated with the update model version.

When extracting the model version, access points indicating corresponding NNR units can be advantageously used. It is also advantageous to be able to determine that the end of a model version has been reached, as it may allow stopping the decoding process.

Once the model version is extracted, it can be used to instantiate a neural network corresponding to the model version.

In a variant, instead of extracting the descriptive data describing the one or more model versions information and the one or more requested model versions, the NNR bitstream is parsed to retrieve the descriptive data and then the descriptive data is used to jump forward into the NNR bitstream and continue the parsing and possibly the decoding at an access point corresponding to a requested version.

So as to take advantage of the invention, a parser or decoder should provide an API that enables exposing the different model versions of a neural network comprised in an NNR bitstream. For instance, there may be a function allowing to determine whether an NNR bitstream comprises a base model version, a function allowing to determine whether an NNR bitstream comprises a model update version, a function allowing to list the model versions comprised in an NNR bitstream, as well as a function allowing to extract a given model version.

The V-SEI specification (ISO/IEC 23002-7) defines the syntax and semantics of video usability information (VUI) parameters and supplemental enhancement information (SEI) messages. The VUI parameters and SEI messages defined are designed to be conveyed within coded video bitstreams in a manner specified in a video coding specification or to be conveyed by other means determined by the specifications for systems that make use of such coded video bitstreams. This may apply to coded video bitstreams like VVC (ISO/IEC 23090-3), although it is intended to be sufficiently generic that it can also be used with other types of coded video bitstreams (e.g. AVC, HEVC . . . ).

VUI parameters and SEI messages can assist in processes related to decoding, display or other purposes. However, unless otherwise specified in a referencing specification, the interpretation and use of the VUI parameters and SEI messages specified in this document is not a required functionality of a video decoder or receiving video system. Although semantics are specified for the VUI parameters and SEI messages, decoders and receiving video systems can simply ignore the content of the VUI parameters and SEI messages or can use them in a manner that somewhat differs from what is specified in the specification.

In addition to the main specification, an amendment to V-SEI is in progress within JVET group to define additional SEI messages, especially the two following ones: NNPFA for neural-network post-filter activation and NNPFC for neural-network post-filter characteristics. The neural-network post-filter characteristics (NNPFC) SEI message specifies a neural network that may be used as a post-processing filter. The use of specified post-processing filters for specific pictures is indicated with neural-network post-filter activation SEI messages. The neural-network post-filter activation (NNPFA) SEI message activates or de-activates the possible use of the target neural-network post-processing filter, identified by nnpfa_target_id, for post-processing filtering of a set of pictures. It is to be noted that there can be several NNPFA SEI messages present for the same picture, for example, when the post-processing filters are meant for different purposes or filter different color components.

The generation of these SEI messages (NNPFC/NNPFA) requires knowing whether a base or an update is indicated. It also requires knowing the relationship between an update and the version it refers to. Therefore, based on an NNR bitstream, it is not straightforward to generate SEI messages as there is a need to parse the headers of all NNR units, especially all NNR NDU units, to determine versions present in the bitstream as well as their relationships.

On the other hand, when using a bitstream such as the one described by embodiments of the invention, obtaining the required information to generate SEI messages is much easier. In particular, only a subset of NNR units' headers have to be parsed to determine the model versions present in the bitstream, as well as their relationship. Extracting a given model version in order to use it in an NNPFC message is also easier in embodiments where access points to NNR units associated to a given model version are encoded into the bitstream.

FIG. 5a provides an example syntax for integrating version description information into the NNR_MPS unit syntax according to an embodiment of the invention. On the right column, u(xx) means that corresponding field (in the left column) is an unsigned integer made of xx bits. Please note that the number of bits indicated is just an example. Depending on considered use cases, different requirements may exist, which may lead to choose different numbers of bits for a given information. This comment also applies to other figures illustrating syntax examples, especially FIGS. 6a, 7a-7c and 8a. When st(v) is indicated in the right column, it means that corresponding field (in the left column) is a string of variable length.

The proposed syntax may include following fields:
versions_description_present_flag: a flag that indicates whether model versions description is present or not in the syntax;
has_base: a flag that indicates whether the NNR bitstream comprises a base model version;
updates_count: an integer that indicates the number of model update versions present in the NNR bitstream;

Then, for each model version present in the bitstream, a version_id value may be defined to indicate a version identifier of said model version. In this proposed syntax, version_id is a string of variable length, similarly to the base_model_id value. Alternatively, it could be an integer value. The version_id allows identifying a model version for a given base model identified by base_model_id.

For each model update version present in the bitstream, a reference_version_id may be defined to indicate the model version on which this incremental model update is based, its reference model. In this proposed syntax, this value is a string of variable length; alternatively, it could be an integer value, which may either correspond to the model version identifier version_id defined for the model version, or the index version_id of the model version in the list of all defined model versions.

For each model version, an integer version_parts_count may be defined that indicates the number of parts for this version. Each part is typically one or more successive NNR units associated to a given model version. Therefore, for each part, a byte offset is indicated in order to determine where this part starts, as well as a length, which is typically a number of NNR units. Alternatively, it could be a length in bytes, but this would require more bits as the value may be significantly large.

As another alternative, it may not be necessary to encode has_base. For instance, updates_count may be coded first, and only if its value is not 0, the Boolean value has_base would be indicated. Else, in the absence of a model update version, when updates_count is zero, has_base is considered to be true as the bitstream necessarily comprises a base model if there is no model update, otherwise, the NNR bitstream would be empty.

While it is proposed to have this syntax integrated in the NNR_MPS unit, it could also be integrated into another existing type or new type of NNR unit carrying information having a bitstream-level scope, meaning carrying information applying to the whole NNR bitstream. For instance, it may be possible to include this syntax in the NNR_STR, or in a newly defined unit aiming at describing version information, for example named NNR_VER unit. In this case the versions_description_present_flag would not be necessary as NNR_VER would be optional, and its presence would indicate the presence of versions description information.

FIG. 5b illustrates an example of NNR bitstream that may be described using the syntax proposed in FIG. 5a. The model versions description information would be present in the NNR_MPS unit 502 coming after the NNR_STR 501 unit starting the NNR bitstream, which would describe the presence of a base model version and of an “update A” model version. As illustrated, NNR units (e.g. NNR_NDU, NNR_AGG, NNR_LPS . . . ) associated to each version may be interleaved. In this example, where the base model comprises the NNR_NDU units 503 and 505 and the “update A” model comprises the NNR_NDU units 504 and 505, there would be two parts for each version, hence two byte offsets and two lengths for each model version.

FIGS. 6a and 6b illustrates another embodiment of the invention. In the context of these figures, it is considered an embodiment where a NNR unit carrying information applying to the whole bitstream comprises the whole model versions description information. Additionally, we also assume that the NNR bitstream is constrained in that the NNR units associated to a given model version must be contiguous, meaning that the NNR units of different model versions cannot be interleaved.

FIG. 6a describes a syntax, for example specified in a NNR_MPS unit, similar to the one proposed in FIG. 5a, except that it is assumed here that, when model versions description is provided, the NNR units of each version must all be contiguous. In other word, with the concept of “parts” described in FIG. 5a, this implies that it would be guaranteed that there is a single part for each model version.

Consequently, there is no need to indicate a versions_parts_count in the syntax of FIG. 6a, and a single access point version_entry_point and a single length, typically corresponding to the number of contiguous NNR units for the model version can therefore be provided.

FIG. 6b illustrates the corresponding NNR bitstream where it is assumed that, when model versions description is provided, the NNR units of each model version are contiguous. Therefore, contrary to FIG. 5b where NNR units of each model version are interleaved, here there is no interleaving. The NNR_NDU units 503 and 504 associated with the base model version appears first in the NNR bitstream, followed by the NNR_NDU units associated with the “update A” model version.

FIGS. 7a, 7b, 7c, and 7d illustrate a further embodiment of the invention. In the context of these figures, it is considered an embodiment where a bitstream level NNR unit carrying information applying to the whole bitstream, for example a NNR_MPS unit, may contain an indication on the model versions present in the NNR bitstream, but no access point. Technically, this may be needed to enable the addition of model version information without requiring that the whole NNR bitstream to be encoded prior to start its serialization, as it would be needed to determine the access points of each model version, for instance.

It is also assumed that, in this embodiment, the NNR bitstream comprises NNR_AGG units representing aggregate NNR units, and that these aggregate NNR units provide the access points and embed in their headers additional model versions description information.

In a variant of this embodiment, explicit model version identifiers are not signaled in the NNR bitstream. Instead, the index of the model version in the list of all model versions comprised in the NNR bitstream is used as an implicit model version identifier. Such a list can be maintained by the encoder, based on the data it has been provided.

In another variant, explicit model version identifiers may be indicated, for instance when the model version identifiers are expressed using a string.

FIG. 7a illustrates a proposed syntax that may be integrated into an NNR unit carrying bitstream level information applying to the whole bitstream, for example a NNR_MPS unit, in order to enable indicating whether a base model is present in the NNR bitstream, using the has_base value, and whether at least one model update is present in the NNR bitstream, using the has_updates value. An optimization may consist in encoding the has_base value only if has_updates is true—or conversely, has_updates may be explicitly encoded only if has_base is true. Indeed, since the stream is not supposed to be empty, the absence of a base model, respectively update model, implies the presence of an update model, respectively a base model.

FIG. 7b is a proposed syntax to be integrated into NNR_AGG unit syntax. An NNR_AGG unit is a bitstream level NNR unit because indication it its header applies to multiple NN units, namely the NNR units comprised in the NNR_AGG unit. This addition allows indicating the relationship between model versions. To do so, it is proposed that, when access points and model versions description are present, the number of update model versions newly described in considered NNR_AGG is encoded using an integer, namely the new_update_versions_count value. Then, for each of these newly described update model versions, an index corresponding to the index of the model version that is referred to by the considered newly described update model version is encoded, using the new_version_reference_idx value. It is considered that the value 0 is reserved for the base model version.

FIG. 7c is a proposed syntax to be integrated into NNR_AGG unit syntax in complement to the proposed addition of FIG. 7b. The two additional lines are the 5th and 6th lines. The 5th line is used to determine whether the current NNR bitstream comprises model version description information based on the flag declared in the NNR_MPS unit or another NNR unit carrying bitstream level information applying to the whole bitstream, as indicated with regards to FIG. 7a. If so, for each NNR unit comprised in the NNR_AGG unit, the index of its associated model version is indicated in the nnr_unit_version_idx[i] table.

As a remark, some NNR units may be associated with several model versions, for example NNR_LPS units or NNR_QNT units. Therefore, an additional test may be done after the proposed one at the 5th line in order to determine whether the considered NNR unit has a type that may be associated to several model versions. If so, instead of a single model version index, a list of model version indexes may be indicated.

Another optimization may consist in defining reserved values that may have a specific meaning, such as “applies to all model versions”. This may for instance be the case of the value 0, in which case the model version index would start at 1 (i.e. the base model version would be indicated using index value 1).

Finally, in a variant, it may also be advantageous to indicate, for each NNR unit, whether it is the last NNR unit associated with the indicated model version. Indeed, this allows a decoder application to determine when it may stop processing a NNR bitstream.

FIG. 7d illustrates an example of NNR bitstream corresponding to this embodiment. The NNR bitstream is made of a first part 601, and a second part 602. In this embodiment, the information described in FIG. 7a is included in the NNR_MPS unit, which is then followed by an NNR_AGG unit, as illustrated by part 701, and possibly other NNR_AGG units after that, similar to the first one, as illustrated by part 602. Each NNR_AGG unit first comprises a header, in which the information described in FIGS. 7b and 7c is present. In particular, the first NNR unit is indicated to be an NNR_NDU unit, with an access point and a model version index corresponding to the base model version (i.e. index 0). On the other hand, the second NNR unit in the NNR_AGG unit is indicated to be an NNR_NDU unit with a model version index corresponding to “update A” (i.e. index 1). As illustrated by the differences between parts 601 and 602, the different model versions may occur in different orders in different NNR_AGG units. Each NNR_AGG unit does not necessarily describe all the model versions present in the NNR bitstream. Part 602 illustrates that a new model version labeled “Update C” is described, while it was not described in part 601. The relationship between model versions can be determined thanks to the information added in NNR_AGG units headers through the syntax proposed with regards to FIG. 7b.

In a variant, a hierarchy of NNR_AGG units can be used to carry multiple model versions in a NNR bitstream. A top-level (“first-level”) NNR_AGG may comprise multiple “second-level” NNR_AGG units, each of the “second-level” NNR_AGG units carrying the NNR units for a given model version. In such embodiment, the top-level NNR_AGG units comprise the access points and associated model version identifiers of the “second-level” NNR_AGG units. This embodiment supports extensibility of the NNR bitstream, where one or more additional model versions can be added to an existing NNR bitstream by adding an additional top-level NNR_AGG unit comprising the “second-level” NNR_AGG unit, the “second-level” NNR_AGG unit comprising an additional model version. The hierarchy of NNR_AGG units may comprise more than two levels.

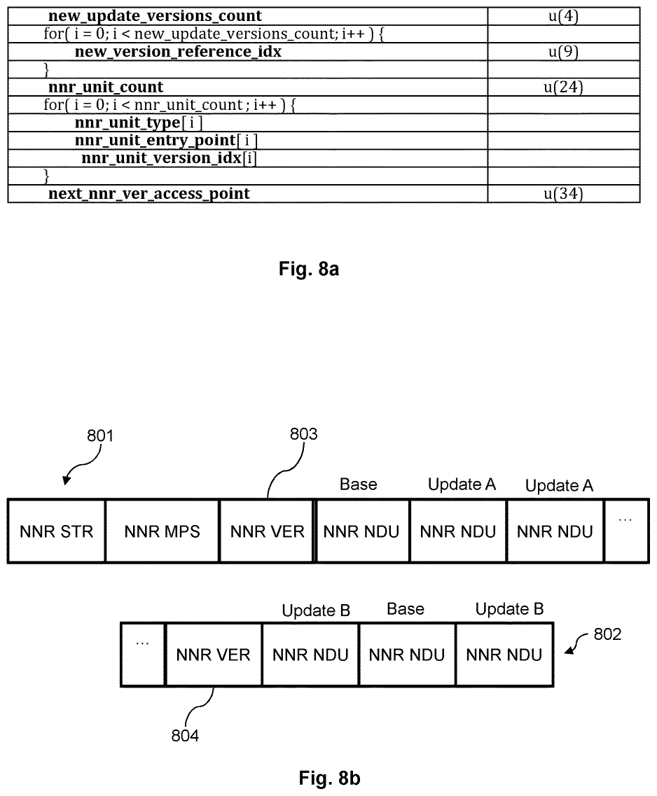

FIGS. 8a and 8b illustrate an embodiment of the invention that is an alternative to the usage of NNR_AGG units in the previous embodiment. In this embodiment, a new type of NNR unit is defined to describe model version information, for instance with the name NNR_VER. An NNR_VER unit is a bitstream level NNR unit that describes all the NNR units that occur after said NNR_VER unit in the NNR bitstream and before the next NNR_VER unit or the end of the NNR bitstream if there is no next NNR_VER unit. A NNR_VER unit is typically used along with the same addition to the NNR_MPS syntax as proposed in FIG. 7a.

FIG. 8a illustrates a proposed syntax for a new kind of NNR unit adapted to describe model version information at different locations throughout an NNR bitstream as illustrated by FIG. 8b. This embodiment is somehow similar to the previous one illustrated by FIG. 7a/7b/7c, except that the usage of NNR_AGG units is not required. Instead, a new kind of NNR unit is used.

First, the number of new update model versions defined in considered NNR_VER unit is indicated using the new_update_versions_count value. Then, for each new update model version, its reference model version is indicated through its index using the new_version_reference_idx value. By definition, the value 0 indicates the based model version. Then, the number of NNR units described by this NNR_VER unit is indicated using the nnr_unit_count value. For each NNR unit, the following properties are defined: its unit type using the nnr_unit_type[i] table of values, an access point indicating its location in the bitstream using the nnr_unit_entry_point[i] table of values and the index of the model version it is associated with using the nnr_unit_version_idx[i] table of values.

Optionally, and as previously described with regards to other embodiments, proposed syntax may be complemented to define, for each model version, an explicit version identifier, e.g. encoded as a string. Similarly, as previously described, for some types of NNR units, a list of associated model version identifiers may be indicated if such NNR units may be associated to more than one model version. The usage of a reserved value may also be considered to indicate an NNR unit that applies to all model versions.

Finally, an access point to the next NNR_VER unit is indicated using the next_nnr_ver_access_point value. This allows a decoder application to conveniently access next NNR_VER unit without having to parse in-between NNR units' headers. In the absence of such indication, a decoder may use the last described access point to reduce the number of headers to be parsed prior to reaching the next NNR_VER unit. If the considered NNR_VER unit is the last NNR_VER unit of the bitstream, its value is typically set to 0 to indicate this situation.

FIG. 8b illustrates an NNR bitstream corresponding to the embodiment considered relatively to FIG. 8a. The NNR bitstream is made of a first part 801, and a second part 802. In this embodiment, the model version information described in FIG. 7a is included in the NNR_MPS unit, which is then followed by an NNR_VER unit 803 in first part 801. This NNR_VER unit describes the following NNR units in the NNR bitstream, which in this example are NNR_NDU units. The first NNR_NDU unit is associated with the base model version, while the second and the third ones are associated with an update model version labelled “Update A”. The NNR_VER unit 803 also describes that the update model version “Update A”, identified by a version identifier with a value 1, is based on the base model version identified by a version identifier with value 0.

Then, in the second part 802, another NNR_VER unit 804 is inserted in the NNR bitstream. This NNR unit 804 describes a new update model version labelled “Updated B” that for instance depends on the update model version “Update A”. The next NNR_NDU unit is associated with the update model version “Update B” (identified by index 2), whereas the following one is associated to the base model version (identified by index 0). Finally, the last NNR_NDU unit is associated with the update model version “Update B”.

This example illustrates that new model versions may be added throughout the NNR bitstream. It also illustrates that proposed syntax offers flexibility as it allows interleaving NNR units associated to different model versions.

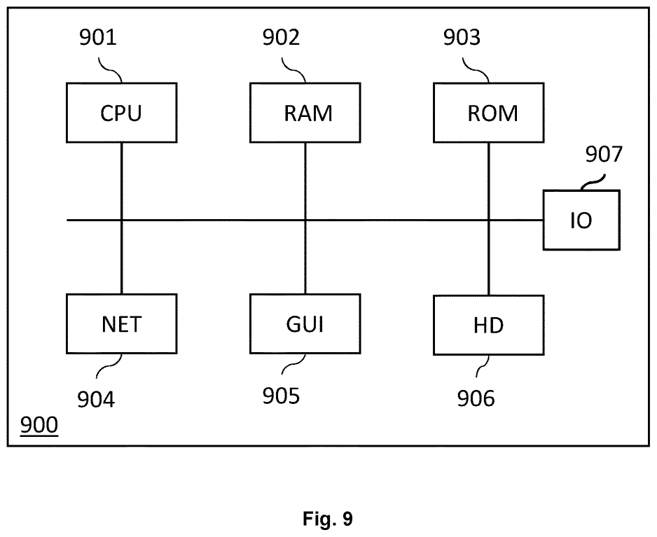

FIG. 9 is a schematic block diagram of a computing device 900 for implementation of one or more embodiments of the invention. The computing device 900 may be a device such as a micro-computer, a workstation or a light portable device. The computing device 900 comprises a communication bus connected to:
a central processing unit 901, such as a microprocessor, denoted CPU;
a random access memory 902, denoted RAM, for storing the executable code of the method of embodiments of the invention as well as the registers adapted to record variables and parameters necessary for implementing the method according to embodiments of the invention, the memory capacity thereof can be expanded by an optional RAM connected to an expansion port for example;
a read only memory 903, denoted ROM, for storing computer programs for implementing embodiments of the invention;
a network interface 904 is typically connected to a communication network over which digital data to be processed are transmitted or received. The network interface 904 can be a single network interface, or composed of a set of different network interfaces (for instance wired and wireless interfaces, or different kinds of wired or wireless interfaces). Data packets are written to the network interface for transmission or are read from the network interface for reception under the control of the software application running in the CPU 901;
a graphical user interface 905 may be used for receiving inputs from a user or to display information to a user;
a hard disk 906 denoted HD may be provided as a mass storage device;
an I/O module 907 may be used for receiving/sending data from/to external devices such as a video source or display.

The executable code may be stored either in read only memory 903, on the hard disk 906 or on a removable digital medium such as for example a disk. According to a variant, the executable code of the programs can be received by means of a communication network, via the network interface 904, in order to be stored in one of the storage means of the communication device 900, such as the hard disk 906, before being executed.

The central processing unit 901 is adapted to control and direct the execution of the instructions or portions of software code of the program or programs according to embodiments of the invention, which instructions are stored in one of the aforementioned storage means. After powering on, the CPU 901 is capable of executing instructions from main RAM memory 902 relating to a software application after those instructions have been loaded from the program ROM 903 or the hard-disc (HD) 906 for example. Such a software application, when executed by the CPU 901, causes the steps of the flowcharts of the invention to be performed.

Any step of the algorithms of the invention may be implemented in software by execution of a set of instructions or program by a programmable computing machine, such as a PC (“Personal Computer”), a DSP (“Digital Signal Processor”) or a microcontroller; or else implemented in hardware by a machine or a dedicated component, such as an FPGA (“Field-Programmable Gate Array”) or an ASIC (“Application-Specific Integrated Circuit”).

Although the present invention has been described hereinabove with reference to specific embodiments, the present invention is not limited to the specific embodiments, and modifications will be apparent to a skilled person in the art which lie within the scope of the present invention.

Many further modifications and variations will suggest themselves to those versed in the art upon making reference to the foregoing illustrative embodiments, which are given by way of example only and which are not intended to limit the scope of the invention, that being determined solely by the appended claims. In particular the different features from different embodiments may be interchanged, where appropriate.

Each of the embodiments of the invention described above can be implemented solely or as a combination of a plurality of the embodiments. Also, features from different embodiments can be combined where necessary or where the combination of elements or features from individual embodiments in a single embodiment is beneficial.

In the claims, the word “comprising” does not exclude other elements or steps, and the indefinite article “a” or “an” does not exclude a plurality. The mere fact that different features are recited in mutually different dependent claims does not indicate that a combination of these features cannot be advantageously used.

1. A method of encoding one or more versions of a neural network model in a Neural Network Representation, NNR, bitstream of logical units, the method comprising:
generating descriptive data describing at least some of the one or more versions of the neural network model;
encoding the descriptive data and the one or more versions of the neural network model in logical units of the NNR bitstream, the descriptive data being encoded in one or more logical units comprising information applying to multiple logical units.

2. The method of claim 1, wherein the descriptive data comprises at least one of the following:
indication of a type of a version of the neural network model;
indication of a number of versions of the neural network model corresponding to an update of the neural network model;
indication of an identifier of a version of the neural network model;
indication of a dependence of a version of the neural network model with another version of the one or more versions of the neural network model;
indication of a creation time of a version of the neural network model;
indication ordering different versions of the neural network model;
indication of a complexity of a version of the neural network model; human-readable description of a version of the neural network model.

3. The method of claim 1, wherein the descriptive data is encoded in a logical unit comprising information applying to the whole NNR bitstream.

4. The method of claim 1, wherein at least some of the descriptive data is encoded in a logical unit comprising information applying to a subset of the logical units of the NNR bitstream.

5. The method of claim 4, wherein at least some of the descriptive data is encoded in a logical unit comprising information applying to the whole NNR bitstream.

6. The method of claim 1, wherein at least some of the descriptive data is encoded in a header of a logical unit aggregating two or more logical units of the NNR bitstream.

7. The method of claim 1, wherein the descriptive data comprise an access point associated with a version of the neural network model, the access point referencing a logical unit of the NNR bitstream corresponding to this version of the neural network model.

8. A method of decoding one or more versions of a neural network model from a Neural Network Representation, NNR, bitstream of logical units, the method comprising:
decoding descriptive data describing at least some of the one or more versions of the neural network model, the descriptive data being decoded from one or more logical units comprising information applying to multiple logical units;
decoding the one or more versions of the neural network model in logical units of the NNR bitstream based on the descriptive data.

9. (canceled)

10. A non-transitory_computer-readable storage medium storing instructions of a computer program for implementing the method of claim 1.

11. (canceled)

12. A device for encoding one or more versions of a neural network model in a Neural Network Representation, NNR, bitstream of logical units, the device comprising a processor configured for:
generating descriptive data describing at least some of the one or more versions of the neural network model;
encoding the descriptive data and the one or more versions of the neural network model in logical units of the NNR bitstream, the descriptive data being encoded in one or more logical units comprising information applying to multiple logical units.

13. A device for decoding one or more versions of a neural network model from a Neural Network Representation, NNR, bitstream of logical units, the device comprising a processor configured for:
decoding descriptive data describing at least some of the one or more versions of the neural network model, the descriptive data being decoded from one or more logical units comprising information applying to multiple logical units;
decoding the one or more versions of the neural network model in logical units of the NNR bitstream based on the descriptive data.
